(19) United States
(12) Patent Application Publication
(10) Pub. No.: US 2024/0331789 A1
(43) Pub. Date: Oct. 3, 2024

(54) SEMICONDUCTOR MEMORY DEVICE, CONTROL METHOD, AND CONTROL DEVICE

(71) Applicant: Winbond Electronics Corp., Taichung City (TW)

(72) Inventor: Takahiko Sato, Yokohama (JP)

(73) Assignee: Winbond Electronics Corp., Taichung City (TW)

(21) Appl. No.: 18/595,877

(22) Filed: Mar. 5, 2024

(30) Foreign Application Priority Data
Mar. 28, 2023 (JP) 2023-050712

(51) Int. Cl. G11C 29/12

(52) U.S. Cl. CPC G11C 29/12005; G11C 2029/1204

(57) ABSTRACT

A semiconductor memory device includes a plurality of word lines, a bit line, a memory cell array, a sense amplifier, and an adjustment unit. The memory cell array includes a plurality of memory cells, wherein each of the plurality of memory cells is connected to one of the plurality of word lines and the bit line. The sense amplifier is connected to the bit line. The adjustment unit counts the number of erroneously-read memory cells whose read values are different from an expected value during a data reading operation of the memory cell while changes a parameter related to a condition of a sensing operation of the sense amplifier. The adjustment unit adjusts a value of the parameter so that the number of erroneously-read memory cells is the minimum.

### CROSS REFERENCE TO RELATED APPLICATIONS

This application claims priority of Japan Patent Application No. JP2023-050712, filed on Mar. 28, 2023, the entirety of which is incorporated by reference herein.

### BACKGROUND OF THE INVENTION

### Field of the Invention

The present invention relates to a semiconductor memory device, a control method, and a control device.

### Description of the Related Art

A semiconductor memory device comprises a memory cell array composed of a plurality of memory cells and is provided with sense amplifiers corresponding to a plurality of bit lines connected to the memory cell array. During the data reading, the sense amplifiers detect and amplify the data read from the memory cells and provide the read data to the bit lines. During the data writing, the sense amplifiers transfers the written data to the bit lines.

A cross-coupled-latch type sense amplifier is known. However, due to manufacturing differences in the elements constituting the sense amplifier, mismatch (for example, mismatch in threshold voltages) is induced, which results in invalid sensing and mis-operations.

In order to avoid such mis-operations, a sense amplifier is provided, for example, in Japan Patent Publication No. 2019-040660, and its structure is not easily affected by the difference in transistor characteristics.

However, in terms of cost or integration, it is not desirable to substantially change the structure of the sense amplifier.

### BRIEF SUMMARY OF THE INVENTION

The present invention provides a semiconductor memory device, a control method, and a control device, which can avoid mis-operations caused by manufacturing differences of transistors constituting a sense amplifier without changing the structure of the sense amplifier.

An exemplary embodiment of a semiconductor memory device comprises a plurality of word lines, a bit line, a memory cell array, a sense amplifier, and an adjustment unit. The memory cell array comprises a plurality of memory cells, wherein each of the plurality of memory cells is connected to one of the plurality of word lines and the bit line. The sense amplifier is connected to the bit line. The adjustment unit counts the number of erroneously-read memory cells whose read values are different from an expected value during a data reading operation of the memory cell while changes a parameter related to a condition of a sensing operation of the sense amplifier. The adjustment unit adjusts a value of the parameter so that the number of erroneously-read memory cells is the minimum.

An exemplary embodiment of a control method of a semiconductor memory device is provided. The semiconductor memory device comprises: a plurality of word lines and a bit line; a memory cell array comprising a plurality of memory cells, wherein each of the plurality of memory cells is connected to one of the plurality of word lines and the bit line; and a sense amplifier connected to a pair of bit lines. The control method comprises: counting the number of erroneously-read memory cells whose read values are different from an expected value during a data reading operation of the memory cell while changing a parameter related to a condition of a sensing operation of the sense amplifier, and adjusting a value of the parameter so that the number of erroneously-read memory cells is the minimum. An exemplary embodiment of a control device disposed in a semiconductor memory device is provided. The semiconductor memory device comprises: a plurality of word lines and a bit line; a memory cell array comprising a plurality of memory cells, wherein each of the plurality of memory cells is connected to one of the plurality of word lines and the bit line; and a sense amplifier connected to a pair of bit lines. The control device counts the number of erroneously-read memory cells whose read values are different from an expected value during a data reading operation of the memory cell while changes a parameter related to a condition of a sensing operation of the sense amplifier. The control device adjusts a value of the parameter so that the number of erroneously-read memory cells is the minimum.

### BRIEF DESCRIPTION OF THE DRAWINGS

FIG. 1 is a schematic block diagram of a semiconductor memory device of a first embodiment;

FIG. 2 is a schematic diagram of a structure of a memory cell array;

FIG. 3 is a schematic diagram showing relationship between a sense amplifier and a memory cell;

FIGS. 4A-4D are schematic diagrams showing changes in voltages of bit lines bl and blx that are sensed;

FIGS. 5A-5D are schematic diagrams showing changes in voltages of bit lines bl and blx that are sensed;

FIG. 6 is a schematic diagram showing a relationship between the number Y of cells that operate abnormally and the parameter X;

FIG. 7 is a flow chart of a control operation performed by an adjustment unit;

FIG. 8 is a schematic block diagram of a semiconductor memory device of a second embodiment; and

FIG. 9 is a schematic block diagram of a structure of a semiconductor memory device.

### DETAILED DESCRIPTION OF THE INVENTION

### First Embodiment

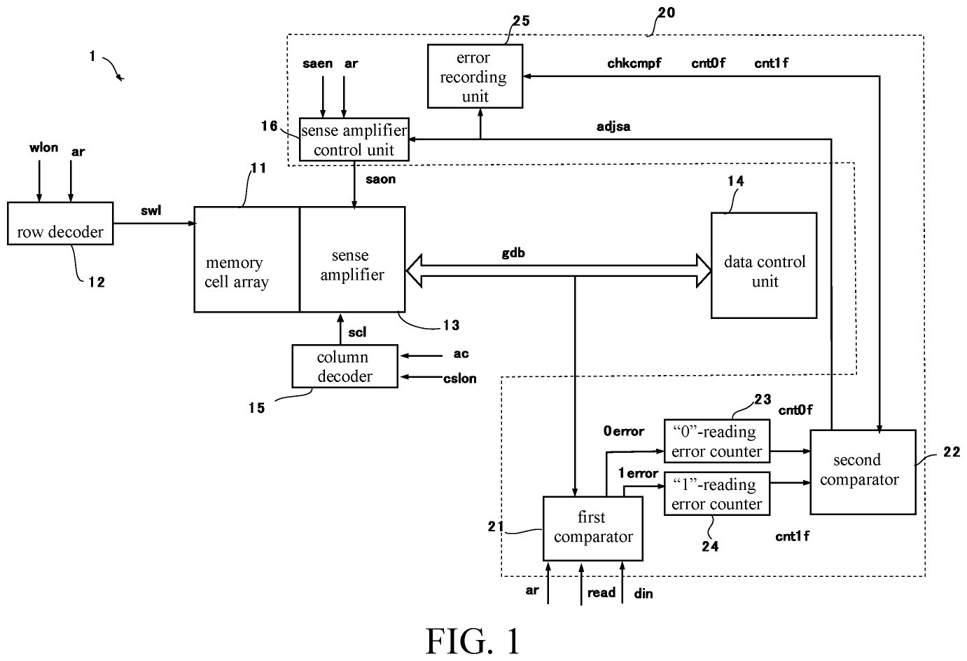

Refer to FIG. 1, a semiconductor memory device 1 is, for example, a volatile memory. The semiconductor memory device 1 comprises a memory cell array 11, a row decoder 12, sense amplifiers 13, a data control unit 14, a column decoder 15, and a sense amplifier control unit 16. In addition, the adjustment unit 20 of the semiconductor memory device 1 comprises a first comparator 21, a second comparator 22, a “0”-reading error counter 23, an “1”-reading error counter 24, and an error recording unit 25, which will be described in detail later. In addition, the sense amplifier control unit 16 is one portion of the adjustment unit 20.

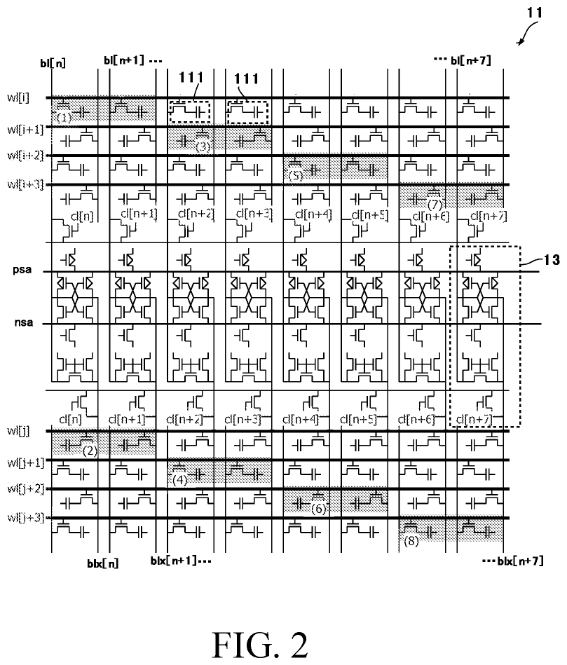

Here, the memory cell array 11 will be described with reference to FIG. 2. In addition, FIG. 2 is a schematic diagram showing the memory cell array 11 in detail, but the number of memory cells or structure of the memory cells is not limited thereto. If it is desired to distinguish the elements by the positions, the reference symbol [ ] will be given to specify and distinguish the elements. The memory cell array 11 comprises a plurality of memory cells 111 that are arranged two-dimensionally in columns and rows. The memory cells 111 in the same row are connected to the same word line wl; the memory cells 111 in the same column are connected to the same pair of bit lines bl and blx. One pair of bit lines bl and blx are connected to one column line cl. A data reading operation or a data writing operation is performed on the plurality of memory cells 111 connected to the same word line wl at the same time. The memory cell array 11 also comprises a plurality of sense amplifiers 13 disposed between the word lines wl[i]−wl[i+3] and wl[j]˜wl[j+3].

Returning to FIG. 1, the row decoder 12 decodes a row address specifying the row direction of the memory cell array 11. Then, a word line wl is selected based on the decoded result, and voltages required for data writing or reading data are applied to the selected word line. Specifically, the row decoder 12 inputs a word line signal swl that is activated the word line wl selected by the row address information ar at the timing specified by the word line activation signal wlon to the memory cell array 11. In addition, the address information (such as the row address information ar) or the word line activation signal wlon is input to each element from a memory controller (not shown) through a command input/output unit (not shown in FIG. 1).

When the data reading operation is performed, the sense amplifiers 13 transmit the data that is read from the memory cell array 11 to the data control unit 14. Specifically, the sense amplifiers 13 are controlled by the sense amplifier control unit 16. The sense amplifier control unit 16 selects a word line wl according to the row address information ar used to select the to-be-sensed row column of the memory cell array 11. At the time point when a sense amplifier enabling signal saen is valid, a sense amplifier activation signal saon for activating specified sense amplifiers 13 is set to be valid and output to the sense amplifiers 13. The sense amplifiers 13 operate according to the sense amplifier activation signal saon. In this way, the sense amplifiers 13 read the data information gdb from the specified memory cells 111 of the memory cell array 11 and transmits the data information gdb to the data control unit 14 through a data bus. In addition, when the data writing operation is performed, the sense amplifiers 13 transfer the data information gdb in the data control unit 14 to the memory cell array 11 through the data bus. The details of the sense amplifiers 13 will be described later.

Because the data control unit 14 is input with writing data or reading data, the data control unit 14 will keep the data and input or output the data.

The column decoder 15 decodes a column address specifying a column direction of the memory cell array 11. Then, according to the decoded result, the data is transmitted to the sense amplifiers 13 during the data writing operation, and the data is read from the sense amplifiers 13 at during the data reading operation. Specifically, the column decoder 15 validates the column lines selected by a column address information ac at the time point specified by a column line activation signal cslon. A column line signal scl is input to the sense amplifiers 13, and the bit lines bl and blx corresponding to the column address are connected to the data bus so that the data information gdb can be transmitted.

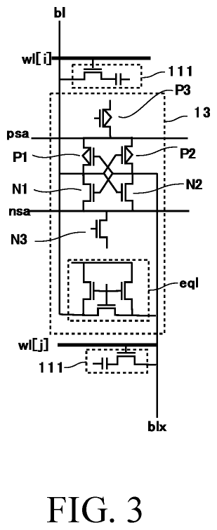

Refer to FIG. 3, the word line wl[i] is connected to one memory cell 111, and the word line wl[j] is connected to another memory cell 111. A sense amplifier 13 is disposed between the word lines wl[i] and the word line wl[j] arranged along the row direction. The sense amplifier 13 is connected to a pair of bit lines bl and blx orthogonal to the word line wl[i] and the word line wl[j]. The bit lines bl and blx are connected to an equalizer eql.

The sense amplifier 13 may be implemented by any configuration as long as the function of the sense amplifier 13 can be achieved. In the embodiment, a common cross-coupled latch-type sense amplifier is used to implement the sense amplifier 13. The common cross-coupled latch-type sense amplifier comprises two NMOS transistors and two PMOS transistors connected between a pair of bit lines. Since such sense amplifier has a common structure, the sense amplifier can operate easily. The sense amplifier 13 comprises PMOS transistors P1-P3 and NMOS transistors N1-N3. The gate of the PMOS transistor P1 is connected to the gate of the NMOS transistor N1, and the gate of the PMOS transistor P2 is connected to the gate of the NMOS transistor N2. In addition, the drain of the PMOS transistor P1 is connected to the drain of the NMOS transistor N1, and the drain of the PMOS transistor P2 is connected to the drain of the NMOS transistor N2. The source of PMOS transistor P1, the source of PMOS transistor P2, and the drain of PMOS transistor P3 are connected through a power line psa. The source of NMOS transistor N1, the source of NMOS transistor N2, and the drain of the NMOS transistor N3 are connected through a power line nsa. The power is provided to a pair of PMOS transistors through the PMOS transistor P3, and the power is provided to a pair of NMOS transistors through the NMOS transistor N3. The power can be provided to the PMOS transistors P1 and P2 of the sense amplifiers 13 through a PMOS transistor P3. In addition, the power can be provided to the NMOS transistors N1 and N2 of the sense amplifiers 13 through an NMOS transistor N3.

In this case, it is preferable that the threshold voltage vtp of the PMOS transistor P1 and the threshold voltage vtn of the NMOS transistor N1 of the sense amplifier 13 are equal to the set threshold voltages vtp0 and vtn0, respectively. However, due to differences in manufacture, the threshold voltage vtp of the PMOS transistor P1 and the threshold voltage vtn of the NMOS transistor N1 of the sense amplifier 13 may not be the same as the set threshold voltages vtp0 and vtn0, respectively, which induces differences Δvtp and Δvtn from the set values. This situation will be discussed below.

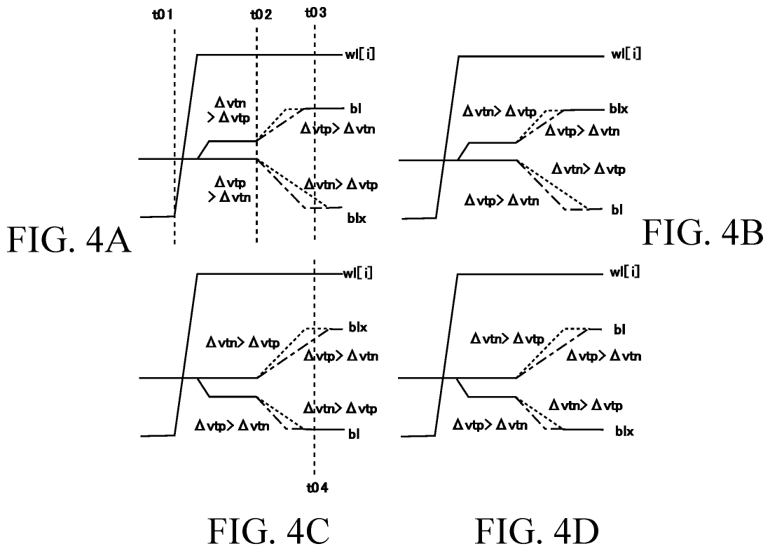

In the sense amplifier 13, when the equalizer eql is invalid, the balance between the bit line bl and the bit line blx is released, the word line wl[i] is activated, and the sense amplifier 13 is enabled through the PMOS transistor P3 and the NMOS transistor N3 to operation for performing the sensing operation. In this case, when a high-level bit “1” is read from a memory cell to the bit line bl, the changes in the sensed voltages of the bit lines bl and blx are shown in FIG. 4A. In addition, in the embodiment, when one bit line among a pair of bit lines is used as a reference, it can be used as a data signal line.

As shown in FIG. 4A, at time t01, the word line wl[i] is activated, the equalizer eql is disabled, and the bit line bl is at a high level. Then, the sense amplifier 13 is turned on at time t02. At this time, the rising speed of the bit line bl that is present when Δvtn is greater than Δvtp (Δvtn>Δvtp) is greater than the rising speed of the bit line bl that is present when Δvtp is greater than Δvtn (Δvtp>Δvtn). On the contrary, the falling speed of the bit line blx that is present when Δvtp is greater than Δvtn (Δvtp>Δvtn) is greater than the falling speed of the bit line blx that is present when Δvtn is greater than Δvtp (Δvtn>Δvtp). That is, when Δvtn is greater than Δvtp (Δvtn>Δvtp), the time point when the voltage on the bit line blx becomes stable is later.

FIG. 4B shows the case where a high-level bit “1” is read to the bit line blx. The other conditions are all the same as the case of FIG. 4A. In FIG. 4B, when Δvtn is greater than Δvtp (Δvtn>Δvtp), the time point when the voltage on the bit line bl becomes stable is later.

FIG. 4C shows the case where a low-level bit “0” is read to the bit line bl. The other conditions are all the same as the case of FIG. 4A. In FIG. 4C, when Δvtp is greater than Δvtn (Δvtp>Δvtn), the time point when the voltage on the bit line blx becomes stable is later.

FIG. 4D shows the case where the a low-level “0” is read to the bit line blx. The other conditions are all the same as the case of FIG. 4A. In FIG. 4D, when Δvtp is greater than Δvtn (Δvtp>Δvtn), the time point when the voltage on the bit line bl becomes stable is later.

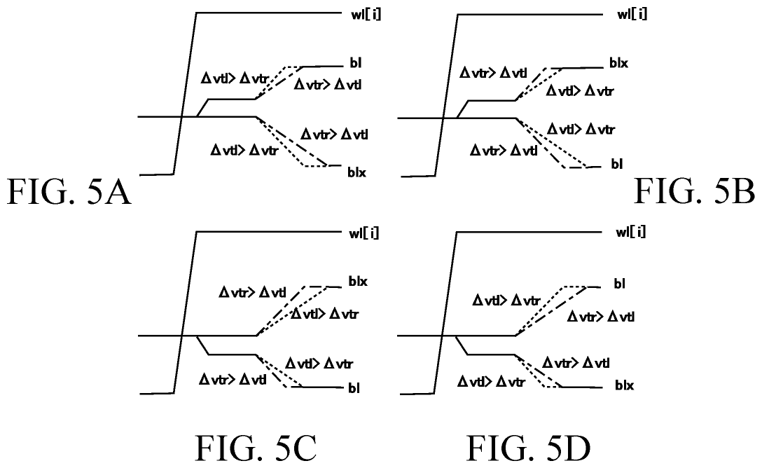

Next, the threshold voltage vtl of the NMOS transistor N1 and the threshold voltage vtr of the NMOS transistor N2 are different from the set threshold voltages by Δvtl and Δvtr respectively. In detail, it is preferable that the threshold voltage vtl of the NMOS transistor N1 and the threshold voltage vtr of the NMOS transistor N2 in of the sense amplifier 13 are equal to the set threshold voltage, however, due to difference in manufacture, the threshold voltage vtl of the NMOS transistor N1 and the threshold voltage vtr of the NMOS transistor N2 may not be the same as the set threshold voltages, which is shown in FIG. 5. Moreover, the description related to the features of FIGS. 5A-5D that are the same as FIGS. 4A-4D will be omitted.

FIG. 5A shows the case where a high-level bit “1” is read to the bit line bl. When the sense amplifier 13 is turned on, the rising speed of the bit line bl that is present when Δvtl is greater than Δvtr (Δvtl>Δvtr) is greater than the rising speed of the bit line bl that is present when Δvtr is greater than Δvtl (Δvtr>Δvtl); the falling speed of the bit line blx that is present when Δvtl is greater than Δvtr (Δvtl>Δvtr) is greater than the falling speed of the bit line blx that is present when Δvtr is greater than Δvtl (Δvtr>Δvtl). In other words, when Δvtr is greater than Δvtl (Δvtr>Δvtl), the time point when the voltage on the bit line blx becomes stable is later.

FIG. 5B shows the case where a high-level bit “1” is read to the bit line blx. The other conditions are all the same as the case of FIG. 5A. In FIG. 5B, when Δvtl is greater than Δvtr (Δvtl>Δvtr), the time point when the voltage on the bit line bl becomes stable is later.

FIG. 5C shows the case where a low-level “0” is read to the bit line bl. The other conditions are all the same as the case of FIG. 5A. In FIG. 5C, when Δvtl is greater than Δvtr (Δvtl>Δvtr), the time point when the voltage on the bit line blx becomes stable is later.

FIG. 5D shows the case where a low-level “0” is read to the bit line blx. The other conditions are all the same as the case of FIG. 5A. In FIG. 5D, when Δvtr is greater than Δvtl (Δvtr>Δvtl), the time point when the voltage on the bit line bl becomes stable is later.

According to FIG. 4 and FIG. 5, in the sensing operation, when there are differences in manufacture of the sense amplifiers 13, the time to reach the desired voltage will be different. Generally, it is better to shorten the reading time in the sensing operation, but due to the differences in the manufacture of the sense amplifiers 13, the time to reach the desired voltage is lengthened. In this way, in the set reading time, mis-operation may be induced. On the other hand, in order to stabilize the voltage value, the reading time is set to be longer, however, which may cause a delay.

Taking FIG. 4A as an example, in the case of reading “1” from the bit line bl, at the time point for sensing, that is, at time t03, if Δvtp is greater than Δvtn (Δvtp>Δvtn), the voltage value remains stable; but if Δvtn is greater than Δvtp (Δvtn>Δvtp), the voltage value of the bit line blx does not drop to the smallest value, which may induce mis-operation. On the other hand, as shown in FIG. 4C, in the case of reading “0” from the bit line bl, at time t04, if Δvtn is greater than Δvtp (Δvtn>Δvtp), the voltage value remains stable; but if Δvtp is greater than Δvtn (Δvtp>Δvtn), the voltage value of the bit line blx does not increase to the largest value, which may induce mis-operation. In addition, the same situation may occur in any one of FIGS. 4(B) and 4(D) and FIGS. 5(B) and 5(D).

Accordingly, due to differences in manufacture of the transistors, in the data reading operations of “1” and “0”, mis-operation occurs in some transistors, while mis-operation does not occur in some transistors. In other words, even under the same parameter values, if the number of erroneously-read cells in the reading operation of “1” is greater, the number of erroneously-read cells in the reading operation of “0” is less; otherwise, if the number of erroneously-read cells in the reading operation of “0” is greater, the number of erroneously-read cells in the reading operation of “1” is less.

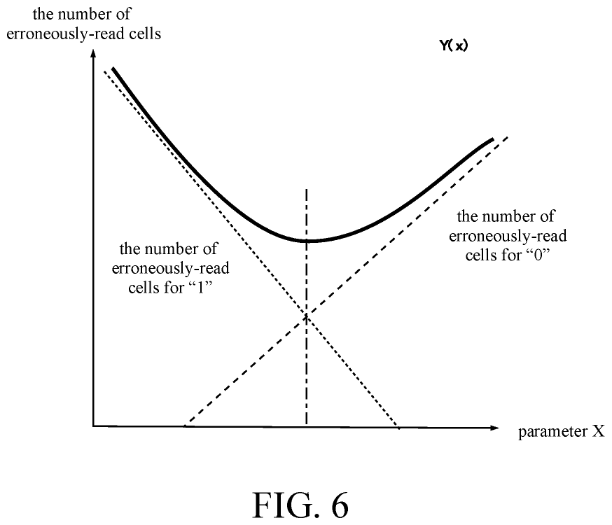

The relationship between the number of erroneously-read cells and a parameter during the reading operation may be a specific relationship of FIG. 6. FIG. 6 shows the relationship between the number of erroneously-read cells Y (X) and the parameter X in the cases shown in FIGS. 4 and 5. The parameter X in FIG. 6 is the deviation between the threshold voltages vtn and vtp and their set values, that is, the difference between Δvtn and Δvtp (Δvtn−Δvtp). Here, since the threshold voltage vtn can be changed through a reverse bias voltage, the parameter X can be changed by changing the value of the threshold voltage vtn. For example, in the case of FIGS. 4A-4D, if the value of (Δvtn−Δvtp) is smaller (that is, if Δvtn is smaller and Δvtp is greater), the number of erroneously-read cells for the reading operation of “1” among the number Y of erroneously-read cells will increase; if the value of (Δvtn−Δvtp) is greater (that is, if Δvtn is greater and Δvtp is smaller), the number of erroneously-read cells for the reading operation of “0” in the number Y of erroneously-read cells will increase. Therefore, relative to the parameter X, the number of erroneously-read cells is shown with a downward-convex curve, and it is known that there is an optimal condition for the parameter, that is, the number of erroneously-error cells for “1” and the number of erroneously-read cells for “0” are very few, which makes the total number of erroneously-read cells minimal. Then, it can be known that for the parameter with the minimum value, the number of erroneously-read cells in the reading operation of the data “1” on one side of the curve is greater, and the number of erroneously-read cells in the reading operation of the data “0” on the other side of the curve is greater. Therefore, the number of erroneously-read memory cells that has a greater value is used as the number of erroneously-read memory cells, and the values of the above-mentioned parameters are obtained through adjustment so that the number of erroneously-read memory cells is the smallest. Thus, mis-operation that is induced due to differences in manufacture of the transistors constituting the sense amplifiers can be prevented.

Therefore, the present embodiment is provided with an adjustment unit 20. The adjustment unit 20 adjusts the value of the parameter to determine the optimal value of the parameter so that the total number of erroneously-read cells is minimized. For example, the adjustment unit 20 performs an error checking operation on cells that are selected by a parameter, changes the parameter, performs the error checking operation on the selected cells again, and counts the number of erroneously-read cells for “1” and the number of erroneously-read cells for “0” read errors in each condition, thereby obtaining the total number of erroneously-read cells. Then, if the number of erroneously-read cells is found to be the smallest for the parameter X1, the adjustment unit 20 corrects the threshold voltage vtn of the NMOS transistors N1 and N2 of the sense amplifier 13 based on the parameter X1.

Here, in the above example, the reverse bias voltage that affects the threshold voltage of the NMOS transistors of the sense amplifier 13 is used as the parameter X; in addition, the power supply voltage of the sense amplifier 13 and the balance voltage of the bit lines bl and blx can also be used as the preferred parameter X. It is easy to induce the differences in the above voltages due to manufacture, however, they can also be changed as parameter values, so it is better to use these voltages. It will be explained with FIG. 4A. When the power supply voltage is increased while the balance voltage of the bit lines bl and blx is maintained, the amount of charges stored in the memory cell 111 will increase toward the side of “1” based on the balance voltage of the bit lines bl and blx. Thus, the voltage difference between the bit lines bl and blx during the period from time t01 to time t02 will increase, which makes “1” to be read easily. Conversely, if the balance voltage of the bit lines bl and blx is decreased while the power supply voltage is maintained, the amount of charges accumulated in the memory cell will also increase toward the side of “1”, which makes “1” to be read easily. From the above description, the adjustment unit 20 can use the power supply voltage of the sense amplifier 13 and the balance voltage of the bit lines bl, blx as parameters X, count the number of erroneously-read cells for “1” and the number of erroneously-read cells for “0”, and set the parameter corresponding to the total number of erroneously-read cells that is the minimum. In addition, it is easy to change the reverse bias voltage of the NMOS transistors, and, thus, it is preferable that the reverse bias voltage serves as a parameter.

The adjustment unit 20 will be described. Specifically, the adjustment unit 20 performs the error checking operation sequentially on the selected memory cells 111 in the memory cell array 11 while changing the parameter(s) related to the conditions of the sensing operation of the sense amplifier 13. Then, when there is any erroneously-read cell for “1” or “0” in the memory cells 111 of the respective parameter values, the adjustment unit 20 counts the number of erroneously-read cells and then sets the parameter(s) so that the number of erroneously-read cells in the reading operation of “1” and the number of erroneously-read cells in the reading operation of “0” are the smallest.

The data information gdb is input to the first comparator 21 through the data bus. In addition, an input signal (an expected-value data signal) din, a read signal read, and the row address information ar are also input to the first comparator 21. The input signal din is a signal that is input from an external terminal of the semiconductor memory device 1 during a pre-shipment test or a checking operation on the memory operation of the memory controller and that represents expected value data for checking. The read signal read is a signal that becomes valid during the reading operation. When the to-be-read memory cell 111 is connected to the side of the bit line blx according to the row address information ar, the data whose phase is opposite to the data information gdb in the data bus will be read from the memory cell 111. Thus, the row address information ar is used for converting the data on the memory cell 111. The first comparator 21 operates only when the read signal read is valid, that is, the first comparator 21 operates only in the reading operation.

The first comparator 21 performs the error checking operation according to the input signal din and the data information gdb and generates error information signals 1error and 0error which respectively represent the number of erroneously-read memory cells for “1” and the number of erroneously-read memory cells for “0” during the reading operation. Such an error information signal only needs to indicate the number of erroneously-read memory cells. However, in the embodiment, the error information signals 1error and 0error comprise the position information of the erroneously-read bits of the data when “1” and “0” are read, respectively. Specifically, each of the input signal din and the data information gdb is composed of bits. Since the input signal din is the correct data (the expected-value data) for checking, the first comparator 21 performs an exclusive OR (XOR) operation (din [N]\hat{ }dt[n]| . . . |din[1]\hat{ }dt[1]|din[0]\hat{ }dt[0]) on the bit information of the input signal din and the bit information dt of the data on the memory cells 111 that is obtained by converting the data information gdb through the row address ar. Then, in the first comparator 21, the error information signal 0error that is obtained by performing an AND operation on the result of the XOR operation and the inverse signal of the input signal din is input to the “0”-reading error counter 23, and the error information signal 1error that is obtained by performing an AND operation on the input signal din is input to the “1”-reading error counter 24.

In response to the input clock pulses, the “0”-reading error counter 23 counts the number of erroneously-read cells in the reading operation of “0” according to the input error information signal 0error, and the “1”-reading error counter 24 counts the number of erroneously-read cells in the reading operation of “1” according to the input error information signal 1error. The signal cnt0f representing the count result of the “0”-reading error counter 23 and the signal cnt1f representing the count result of the “1”-reading error counter 24 are input to the second comparator 22.

The second comparator 22 determines whether the number of erroneously-read cells corresponding to the “0” data on the memory cells represented by the signal cnt0f reaches a maximum value and determines whether the number of erroneously-read cells corresponding to the “1” data on the memory cells represented by the signal cnt1f reaches the maximum value. When the “0”-reading or “1”-reading error counter reaches the maximum value, the control for this parameter terminates. The so-called “maximum value” here is the maximum value of the number of erroneously-read cells set in advance. If the number of erroneously-read cells reaches the maximum value, even if no comparison is performed, it will be known that this value is relatively large, so no comparison is necessary. In addition, in this case, an alarm may be issued as described later.

In addition, the second comparator 22 compares the signal cnt0f and the signal cnt1f and determines which one of the number of erroneously-read cells for “0” and the number of erroneously-read cells for “1” is greater in the reading operation. For example, it is assumed that the parameter is X1, the number of erroneously-read cells in the reading operation of “0” is N, and the number of erroneously-read cells in the reading operation of “1” is M. When N is less than M (N<M), the number M of erroneously-read cells in the reading operation of “1” is determined as the number of erroneously-read cells. The second comparator 22 generates a control signal chkempf, and the control signal chkempf is used to store the obtained number of erroneously-read cells in the error recording unit 25.

Based on the result, the second comparator 22 generates and outputs an adjustment signal adjsa for optimizing the parameters. The adjustment signal adjsa is a signal indicating how to adjust the parameter values. For example, the case where the numbers of erroneously-read cells for all the parameters have been obtained indicates that the parameter values should be adjusted slightly to be smaller/larger. For example, in the case where the number of erroneously-read cells in the reading operation of “1” for the parameter X1 is M and the number L of erroneously-read cells for another parameter X2 (X2>X1) before updating is greater than M (L>M), the adjustment signal adjsa for optimization that is used to set the parameter to be smaller based on the number M of erroneously-read cells. The adjustment signal adjsa is input to the sense amplifier control unit 16. The sense amplifier control unit 16 adjusts the parameter(s) of the sense amplifier 13 based on the information of the adjustment signal adjsa.

In addition, the error recording unit 25 receives and records the adjustment signal adjsa, the control signal chkempf, or the signal cnt1f from the second comparator 22. That is, the error recording unit 25 records the number of erroneously-read cells when “1” or “0” is read and further records how to set the value of the sense amplifier 13 accordingly.

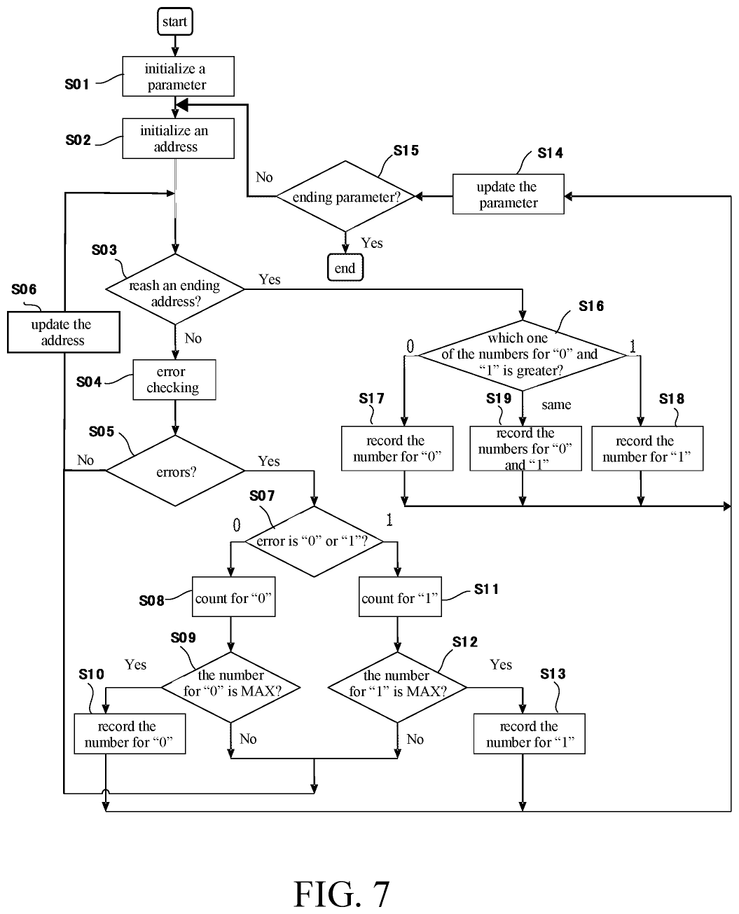

The control performed by the adjustment unit 20 will be described using the flowchart in FIG. 7.

For example, this control is started by starting a pre-shipment test or the like. First, at Step S01, the sense amplifier control unit 16 initializes a parameter of the sense amplifier 13.

In Step S02, the address of the memory cell 111 is initialized. Here, the selection sequence of the memory cells 111 during the control performed by the adjustment unit 20 will be described. During the control performed by the adjustment unit 20, pairs of memory cells 111 in the memory cell array 11 are sequentially evaluated in the sequence of (1)-(8). The pair of memory cells 111 numbered by each of (1)-(8) are connected to the same word line wl, and further connected to the adjacent bit lines bl or blx. Then, the pairs of memory cells 111 numbered with odd reference numbers and the pairs of memory cells 111 numbered with even reference numbers are arranged on the upper and lower sides of the sense amplifier 13 respectively, that is, the sense amplifier 13 is disposed therebetween. For example, the pair of memory cells 111 numbered by (1) are connected to the word line wl[i] and respectively connected to the bit line bl[n] and the bit line bl[n+1]. In addition, the pair of memory cells 111 numbered by (2) are connected to the word line wl[j] and respectively connected to the bit line blx [n] and the bit line blx[n+1]. In addition, the pair of memory cells 111 are arranged on a diagonal line in the memory cell array 11 with respect to the adjacent pair of memory cells 111 in the row direction. For example, the pair of memory cells 111 numbered by (3) are connected to the word line wl[i+1] and respectively connected to the bit line bl [n+2] and the bit line bl[n+3]. Therefore, relative to the pair of memory cells 111 numbered by (1), the pair of memory cells are located on the diagonal. Here, the number of adjacent memory cells 111 with the same reference number in the column direction is equal to 2, but the present application is not limited thereto. If the number of memory cells read in one reading operation increases, the same reference number can be assigned to more memory cells 111 connected to the same word line wl. If the number of memory cells 111 in one reading operation decreases, one reference number can be assigned to one memory cell connected to each word line wl.

In this control, after all the memory cells 111 connected to the same word line are scanned column by column, for example, when there is a defective part in the word line and the detected defective cells are all the memory cells 111 connected to the word line, the number of erroneously-read cells may not detected due to the characteristics of the sense amplifier. Therefore, in the present embodiment, by performing the error checking operation sequentially on the memory cells 111 connected to different word lines and bit lines, the correct number of erroneously-read memory cells can be detected.

The method proceeds to Step S03. The sense amplifier control unit 16 determines whether the address of the memory cell reaches the ending address. For example, in the memory cells 111 shown in FIG. 2, the ending address is an address next to the addresses of the pair of memory cells numbered by (8), so it is an address outside the checking range. That is, the case where the ending address is reached means that the error checking operation has been performed sequentially on the memory cells numbered by (1)-(8) among the memory cells 111 shown in FIG. 2. If the ending address has not been reached yet (No), the method proceeds to Step S04. In Step S04, the error checking operation is performed by the first comparator 21 according to the input signal din and the data information gdb.

Then, the method proceeds to Step S05. If there is no error detected during the operation of the first comparator 21 (No), the method proceeds to Step S06. In Step S06, the address is updated to the address of the next memory cell to be checked for errors. If the first comparator 21 detects an error in Step S05 (Yes), the method proceeds to Step S07. In Step S07, it is determined whether the reading error detected by the first comparator 21 is a reading error during the reading operation of “1” or a reading error during the reading operation of “0”. This operation is essentially the same as described above. In this embodiment, the result of the determination is obtained by the first comparator 21 according to the input signal din and the data information gdb.

If the reading error detected by the first comparator 21 is a read error during the reading operation of “0”, then the method proceeds to Step S08, the error information signal 0error is input to the “0”-reading error counter 23 from the first comparator 21, and the “0”-reading error counter 23 performs a counting-up operation. Then, in Step S09, whether the number of erroneously-read cells has reached the maximum value (MAX) is determined. If it reaches the maximum value, the method proceeds to Step S10, and the “0”-reading error counter 23 inputs the signal cnt0f that indicates the number of erroneously-read cells during the reading operation of “0” to the error recording unit 25.

On the other hand, if the number of erroneously-read cells has not reached the maximum value, the method returns to Step S06. Then, a different memory cell 111 is selected, and the address is updated. Similarly, when the reading error detected by the first comparator 21 is a “1” reading operation, the method proceeds to Step S11, the “1”-reading error counter 24 performs the counting operation. Then, in Step S12, whether the counted number of erroneously-read cells during the reading operation of “1” has reached the maximum value (MAX) is determined. If the maximum value is reached, the method proceeds to Step S13, and the signal cnt1f that indicates the number of erroneously-read cells during the reading operation of “1” is input to the error recording unit 25. On the other hand, if the maximum value is not reached, the method proceeds to Step S06, a different memory cell 111 is selected, and the address is updated.

In any one of Step S10 and Step S13, after the step of recording to the error recording unit 25, the method proceeds to Step S14, and the parameter is updated. The method proceeds to Step S15. If the updated parameter is the pre-set ending parameter (Yes), it is considered that the error checking operation performed on all the parameters in all the memory cells has been completed, and the control terminates. If the parameter is not the pre-set ending parameter (No), then the method proceeds to Step S02 to perform the initialization of the address of the memory cell 111 serving the object of the error checking operation, the predetermined address is input, and a different parameter is used for the error checking of the memory cell 111.

On the other hand, in Step S03, the sense amplifier control unit 16 determines whether the address of the memory cell reaches the ending address. If the result indicates that the address reaches the ending address, then the method proceeds to Step S16. In this case, since the error checking of all the memory cells 111 predetermined for a value of a parameter has been completed, the second comparator 22 determines which one of the number of erroneously-read cells during the reading operation of “0” and the number of erroneously-read cells during the reading operation of “1” is greater. If the number of erroneously-read cells during the reading operation of “0” is relatively greater, then the method proceeds to Step S17 to record this number of erroneously-read cells in the error recording unit 25. If the number of erroneously-read cells during the reading operation of “1” is relatively greater, the method proceeds to Step S18 to record this number of erroneously-read cells and the corresponding parameter in the error recording unit 25. In addition, if the number of erroneously-read cells during the reading operation of “0” is equal to the number of erroneously-read cells during the reading operation of “1”, the method proceeds to Step S19, and both of the numbers are recorded in the error recording unit 25. In this case, the second comparator 22 generates and outputs the adjustment signal adjsa according to the number of erroneously-read cells during the reading operation of “0” and the number of erroneously-read cells during the reading operation of “1”. After Steps S17-S19, the method proceeds to Step S14, and the sense amplifier control unit 16 updates parameters based on the adjustment signal adjsa.

In this way, the error checking operation is performed on all the selected memory cells 111 based on the values of all parameters, thereby obtaining the optimal value of the parameter corresponding to the least number of erroneously-read cells. The adjustment unit 20 adjusts the sense amplifier 13 through the sense amplifier control unit 16 so as to meet the optimum value. Accordingly, the mis-operation caused by differences in manufacture of the transistors constituting the sense amplifier can be avoided without changing the structure of the sense amplifier.

Afterwards, for example, the spare cells in the memory cell array 11 are used for performing a redundancy repair operation on the erroneously-read memory cells that are present under the value of the parameter of the optimal condition so that the number of erroneously-read memory cells under of the optimal condition of the parameter value can decrease.

In addition, the redundancy repair operation can be performed for parameter values around this parameter to minimize the number of erroneously-read cells corresponding to the parameter values around the optimal parameter value. By performing the redundancy repair operation for the parameters near the minimum parameter, the number of erroneously-read cells caused by mis-operation can be further reduced. Therefore, the redundancy repair operation can be performed effectively, and mis-operation can be avoided. That is, the redundancy repair operation is also performed on the parameter values within a predetermined range. The cells that induces reading errors when the reading operation is performed based the parameter values near the optimal parameter, it shows those cells have weakness in reading operation. So those cells have risk of inducing errors also when using the optimal parameter. Therefore, the redundancy repair operation can be also performed for not only the optimum parameter, but also the values of the parameters within a predetermined range around the optimum parameter, which can minimize the number of erroneously-read cells near the value of the optimal parameter. By performing the redundancy repair operation for the parameters near the optimal parameters, the number of erroneously-read cells caused by mis-operation can be further reduced. Therefore, the redundancy repair operation can be performed effectively, and mis-operation can be avoided.

### Second Embodiment

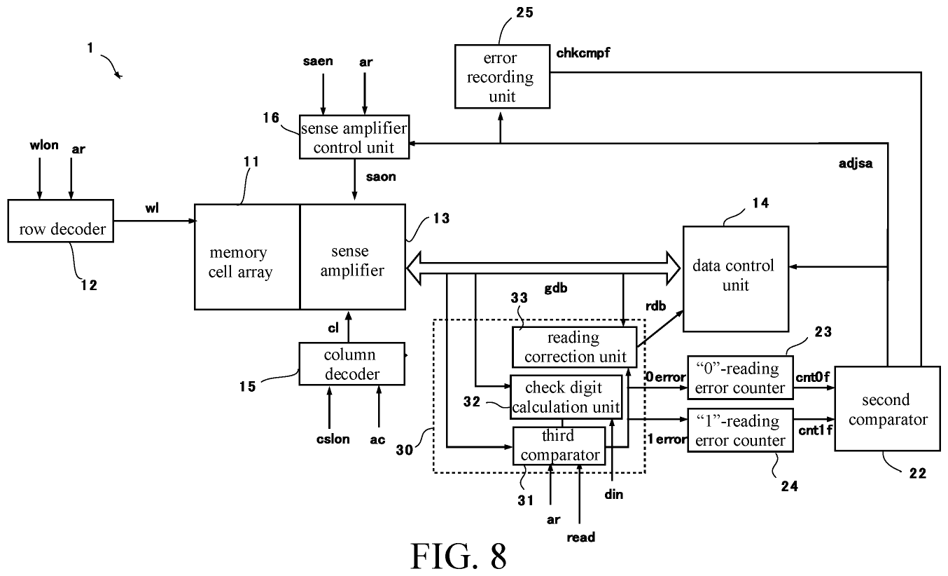

As shown in FIG. 8, the difference between the second embodiment and the first embodiment is that the adjustment unit 20 has an error check and correct (ECC) unit 30. This difference will be described.

The ECC unit 30 may have a general ECC structure. In the embodiment, the ECC unit 30 comprises a third comparator 31 identical to the first comparator 21, a check digit calculation unit 32, and a reading correction unit 33.

In the embodiment, the data information gdb is input to the third comparator 31, the check digit calculation unit 32, and the reading correction unit 33. The input signal din is input to the check digit calculation unit 32. The input signal din is not expected-value data, but it is checking data composed bits comprising information bits and sign bits for generating checking data. In the check digit calculation unit 32, the sign bits are coded through the input signal din and the data information gdb for generating the checking data. The checking data will be input to the third comparator 31. Only when the read signal read is input in the valid state, the third comparator 31 performs an exclusive OR (XOR) operation and an AND operation based on the checking data, the data information gdb, and the row address information ar, similarly to the first embodiment. Then, when it is detected that the error bit data is “1” (that is, when the expected value for the reading of the data “0” is wrong), the third comparator 31 inputs the error information signal 0error to the “0”-reading error counter 23; when it is detected that the error bit data is “0” (that is, when the expected value for the reading of the data “1” is wrong), the third comparator 31 inputs the error information signal 1error to the “1”-reading error counter 24.

In addition, the signal representing the result of the exclusive OR operation in the third comparator 31 is input to the read correction unit 33, and the error is corrected by the reading correction unit 33. The corrected data rdb is input to the data control unit 14. The second comparator 22 performs the same operation as the first embodiment, however, the obtained adjustment signal adjsa is also input to the data control unit 14.

In the embodiment, through performing the error checking operation by the check digit calculation unit 32 of the ECC unit 30, the erroneously-read cells during the reading of “0” and “1” can be easily detected, and their values can be obtained. In addition, in the semiconductor memory device 1 shown in FIG. 8, the optimization of the conditions of the sense amplifiers is performed when the checking signal is input from the outside as the first embodiment. Moreover, in the embodiment of FIG. 8, the reading correction can be performed by the ECC unit 30, while the conditions of the sense amplifiers are optimized.

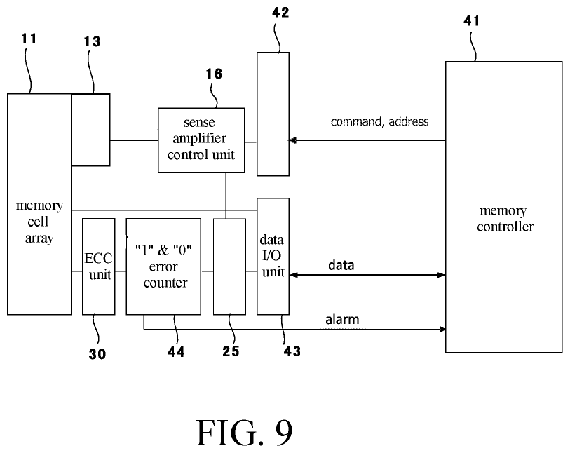

In FIG. 9, the memory controller 41 of the semiconductor memory device 1 is a control unit that controls the semiconductor memory device 1 in an integrated manner. The memory controller 41 sends address information (the row address information, etc.) or instructions (the word line activation signal wlon, etc.) are input to a command input/output (I/O) unit 42. The memory controller 41 further inputs the sense amplifier activation signal saon related to the control of the sense amplifiers among the commands input from the memory controller 41 to the sense amplifier control unit 16. The sense amplifier control unit 16 controls the sense amplifiers 13 as described above. In addition, the input and output of data information (read data or write data) will be performed between the memory controller 41 and a data input/output (I/O) unit 43.

In addition, as mentioned above, the ECC unit outputs a signal that indicates the number of erroneously-read cells when “0” and “1” in the input information from the memory cell array 11 are output to the “1” error and “0” error counter (“1” & “0” error counter) 44 (In FIG. 8, the “1” error counter and the “0” error counter are combined into one error counter). This information is input to the error recording unit 25. In this case, when an abnormality, such as the case where the number of counted erroneously-read cells reaches the maximum value, is detected in the “1” error and “0” error counter 44, a warning signal may be input to the memory controller 41. In response this case, a command that indicates the sense amplifier control unit 16 to perform an adjustment operation is input from the memory controller 41. Then, in this case, the sense amplifier control unit 16 may read the record of the number of erroneously-read cells that is input to the error recording unit 25 and further perform adjustment on the sense amplifiers 13 finely.

In the embodiment, an ECC unit 30 is provided, and the ECC unit 30 can performs an error correction during a reading operation. In addition, by using a conventional ECC control unit, it is preferable to count the number of erroneously-read cells of “1” and “0” without new circuits.

In the above-mentioned embodiment, it is taken as an example that the number of erroneously-read cells in the reading operation of “1” and “0” exceeds a pre-set maximum value, however the present application is not limited thereto. Any predetermined value can also be set as the maximum value. In addition, in the second embodiment, the redundancy repair operation in the first embodiment and the reading correction performed by the ECC unit 30 can also be used together.

In the structure of the second embodiment in which there is the ECC unit 30, a warning is issued when the number of erroneously-read memory cells is greater than or equal to a predetermined value, however, the present application is not limited thereto. For example, even in the structure that does not comprise an ECC unit, as shown in the first embodiment, a warning can be issued when the number of erroneously-read memory cells is greater than or equal to a predetermined value.

In addition, the above-mentioned embodiment is an example where the semiconductor memory device is a volatile memory, however, the present application is not limited thereto. For example, the semiconductor memory device can also be implemented by a non-volatile memory or another semiconductor memory device.

The embodiments and modifications described above are described for easy understanding of the present invention and are not described for limiting the present invention. Therefore, the elements disclosed in the above embodiments and modification examples are intended to include all design changes or equivalents within the technical field of the present invention.

The circuit structures in the above-mentioned embodiments are only examples, and can be appropriately changed, and other various structures can also be adopted.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor memory device comprising:
a plurality of word lines and a bit line;
a memory cell array comprising a plurality of memory cells, wherein each of the plurality of memory cells is connected to one of the plurality of word lines and the bit line;
a sense amplifier connected to the bit line; and
an adjustment unit counting the number of erroneously-read memory cells whose read values are different from an expected value during a data reading operation of the memory cell while changing a parameter related to a condition of a sensing operation of the sense amplifier,
wherein the adjustment unit adjusts a value of the parameter so that the number of erroneously-read memory cells is the minimum.

2. The semiconductor memory device as claimed in claim 1, wherein:
when there is a reading error in reading operations of “1” and “0” data performed on the memory cell reads the “1” and “0” data, the adjustment unit changes the parameter while counts the number of memory cells with reading errors in the reading operation of the “1” data in response to the parameter and further counts the number of memory cells with reading errors in the reading operation of the “0” data in response to the parameter, and
the number of memory cells with reading errors in the reading operation of the “1” data is compared with the number of memory cells with reading errors in the reading operation of the “0” data, the greater number of memory cells is set as the number of erroneously-read memory cells, and then the value of the parameter is adjusted so that the number of erroneously-read memory cells is the minimum.

3. The semiconductor memory device as claimed in claim 2, wherein:
the adjustment unit counts the number of memory cells with errors in the reading operation of the “1” data and the number of memory cells with errors in the reading operation of the “0” data,
if one of the number of memory cells with errors in the reading operation of the “1” data and the number of memory cells with errors in the reading operation of the “0” data is greater than or equal to a predetermined value, the adjustment sets the numbers of memory cells as the number of erroneously-read memory cells without comparison.

4. The semiconductor memory device as claimed in claim 1, wherein:
the memory cell array comprises a spare cell, and
after the adjustment unit adjusts the value of the parameter so that the number of erroneously-read memory cells is the minimum, the semiconductor memory device uses the spare cells to perform a redundancy repair operation on the memory cells with reading errors corresponding to the parameter.

5. The semiconductor memory device as claimed in claim 4, wherein in response to the value of the parameter being in a predetermined range, the semiconductor memory device uses the spare cell to perform the redundancy repair operation on the memory cell with reading errors corresponding to the parameter.

6. The semiconductor memory device as claimed in claim 1, wherein the sense amplifier is a cross-coupled latch-type sense amplifier consisting of two NMOS transistors and two PMOS transistors connected between a pair of bit lines.

7. The semiconductor memory device as claimed in claim 6, wherein the parameter is at least one of a reverse bias voltage of the NMOS transistors constituting the sense amplifier, a power supply voltage of the sense amplifier, and a balance voltage between a pair of bit lines.

8. The semiconductor memory device as claimed in claim 2, wherein:
the adjustment unit comprises a first comparator, and information inputted to the first comparator comprises an expected-value data information composed of bits that does not contain errors and reading data information composed of bits read from the memory cell array, and
the first comparator generates error information from the reading data information, and the error information specifies which memory cell has the reading error in the reading operation of the “1” data or the “0” data of the memory cell.

9. The semiconductor memory device as claimed in claim 2, wherein:
the adjustment unit counts the number of memory cells with reading errors in the reading operation of the “1” data and the number of memory cells with reading errors in the reading operation of the “0” data, and
when one of the number of memory cells with errors in the reading operation of the “1” data and the number of memory cells with errors in the reading operation of the “0” data is greater than a predetermined value, a warning is issued.

10. The semiconductor memory device as claimed in claim 2, wherein:
the adjustment unit comprises an ECC unit that detects and corrects errors,
an error detection operation is performed by the ECC unit to generate error information, and
the error information indicates which memory cell has the reading error in the reading operation of the “1” data or the “0” data.

11. The semiconductor memory device as claimed in claim 1, wherein when the adjustment unit fixes the parameter and selects the memory cells in a predetermined sequence while counts the numbers of memory cells with the reading errors corresponding to each parameter, the adjustment unit does not continuously select the memory cells connected to the same word line.

12. The semiconductor memory device as claimed in claim 1, wherein the semiconductor memory device is a volatile memory.

13. A control method of a semiconductor memory device, wherein the semiconductor memory device comprises:
a plurality of word lines and a bit line;
a memory cell array comprising a plurality of memory cells, wherein each of the plurality of memory cells is connected to one of the plurality of word lines and the bit line; and
a sense amplifier connected to a pair of bit lines;
wherein the control method comprises:
counting the number of erroneously-read memory cells whose read values are different from an expected value during a data reading operation of the memory cell while changing a parameter related to a condition of a sensing operation of the sense amplifier, and
adjusting a value of the parameter so that the number of erroneously-read memory cells is the minimum.

14. A control device disposed in a semiconductor memory device, wherein the semiconductor memory device comprises:
a plurality of word lines and a bit line;
a memory cell array comprising a plurality of memory cells, wherein each of the plurality of memory cells is connected to one of the plurality of word lines and the bit line; and
a sense amplifier connected to a pair of bit lines;
wherein the control device counts the number of erroneously-read memory cells whose read values are different from an expected value during a data reading operation of the memory cell while changes a parameter related to a condition of a sensing operation of the sense amplifier, and
wherein the control device adjusts a value of the parameter so that the number of erroneously-read memory cells is the minimum.
